(19) United States
(12) Patent Application Publication
(10) Pub. No.: US 2023/0076118 A1
(43) Pub. Date: Mar. 9, 2023

(54) DEVICE AND METHOD FOR PREDICTING STATE OF BATTERY

(71) Applicant: ELECTRONICS AND TELECOMMUNICATIONS RESEARCH INSTITUTE, Daejeon (KR)

(72) Inventors: Sungwoo JO, Daejeon (KR); Tae Moon Roh, Daejeon (KR); Sun Kyu Jung, Daejeon (KR)

(21) Appl. No.: 17/842,648

(22) Filed: Jun. 16, 2022

(30) Foreign Application Priority Data
Sep. 3, 2021 (KR) 10-2021-0117418

(51) Int. Cl. G01R 31/387; G01R 31/36; G01R 31/392; G01R 31/3842; G01R 31/367

(52) U.S. Cl. CPC G01R 31/387; G01R 31/3648; G01R 31/392; G01R 31/3842; G01R 31/367

(57) ABSTRACT

Disclosed is a battery state prediction device including a data measurement unit that measures information about a battery and to output first data and a battery state estimation unit that calculates a state of charge (SOC) value of the battery based on the first data, generates second data by pre-processing the first data based on the SOC value, and estimates a state of health (SOH) of the battery based on the second data. The battery state estimation unit calculates the SOC value based on an extended Kalman filter and adjusts a parameter of the extended Kalman filter based on the estimated SOH.

### CROSS-REFERENCE TO RELATED APPLICATIONS

This application claims priority under 35 U.S.C. § 119 to Korean Patent Application No. 10-2021-0117418 filed on Sep. 3, 2021, in the Korean Intellectual Property Office, the disclosures of which are incorporated by reference herein in their entireties.

### BACKGROUND

Embodiments of the present disclosure described herein relate to a device and method for predicting a battery state, and more particularly, relate to a device and method for estimating a state of health (SOH) of a battery based on a state of charge (SOC) estimated based on an extended Kalman filter.

Nowadays, as devices using batteries such as mobile devices and electric vehicles rapidly increase, interest in and research on technology for predicting a battery state is rapidly increasing. When inaccurate results are obtained when the battery state is predicted, permanent damages to battery cells may occur due to overcharge or overdischarge of a battery. Furthermore, because a system may be shut down due to lack of a battery, there is a need for a technology capable of accurately predicting the battery state.

A conventional method of predicting the battery state may estimate battery SOH by using SOC mainly. This method requires the calculation of accurate SOC. However, as time goes on, the calculation error of SOC may be accumulated due to the noise accumulated by a measurement sensor. For this reason, an error in an estimate value for battery SOH may increase. Moreover, SOC may be inaccurately calculated due to unique characteristics of battery cells.

In the meantime, a method of estimating battery SOH by measuring the internal resistance of a battery is also frequently used. However, according to this method, a pre-estimation table including data on the battery state is necessary to estimate battery SOH. Because the pre-estimation table does not reflect all characteristics of each battery, it is impossible to accurately estimate SOH. Besides, there is a problem in that the measurement of internal resistance according to the ambient temperature is essential for each type of battery.

### SUMMARY

Embodiments of the present disclosure provide a device and method for estimating SOH of a battery based on SOC estimated based on an extended Kalman filter.

According to an embodiment of the present disclosure, a battery state prediction device includes a data measurement unit that measures information about a battery and to output first data and a battery state estimation unit that calculates a state of charge (SOC) value of the battery based on the first data, generates second data by pre-processing the first data based on the SOC value, and estimates a state of health (SOH) of the battery based on the second data. The battery state estimation unit calculates the SOC value based on an extended Kalman filter and adjusts a parameter of the extended Kalman filter based on the estimated SOH.

For example, the data measurement unit includes a current sensing unit that measures current information of the battery and to generate current data including the current information, a voltage sensing unit that measures voltage information of the battery and generates voltage data including the voltage information, and a temperature sensing unit that measures temperature change information of the battery and generates temperature change data including the temperature change information. The first data includes the current data, the voltage data, and the temperature change data.

For example, the battery state estimation unit includes an SOC calculation unit that calculates the SOC value and to output the SOC value, a data pre-processing unit that receives the SOC value, to generate the second data by pre-processing the first data based on the SOC value, and outputs the second data, and an SOH estimation unit that receives the second data and estimates the SOH based on the second data.

For example, the SOC calculation unit includes an estimation unit that calculates a prediction SOC value and a prediction error covariance and outputs the prediction SOC value and the prediction error covariance and a correction unit that receives the prediction SOC value and the prediction error covariance, calculates the SOC value and an error covariance based on the prediction SOC value, the prediction error covariance, and the first data, and delivers the SOC value and the error covariance to the estimation unit.

For example, the data pre-processing unit includes a battery cycle measurement unit that measures a battery cycle and an SOC-based data pre-processing unit that pre-processes the first data based on the battery cycle and the SOC value.

For example, the pre-processed first data is stored in a buffer.

For example, the SOH estimation unit performs machine learning.

For example, the machine learning is based on at least one of decision tree learning, a support vector machine, a genetic algorithm, an artificial neural network (ANN), a convolutional neural network (CNN), a feedforward neural network (FNN), a recurrent neural network (RNN), reinforcement learning, and an auto encoder.

For example, the battery state estimation unit outputs a state prediction result of the battery, which is generated based on the estimated SOH, to an outside. The state prediction result of the battery includes at least one of available capacity of the battery, a current level of the battery, or a remaining useful life of the battery.

According to an embodiment of the present disclosure, a method for predicting a battery state includes sensing information about a battery, calculating an SOC value by using an extended Kalman filter based on the sensed information about the battery, measuring a battery cycle of the battery, pre-processing data including the sensed information about the battery based on the SOC value and the battery cycle, determining whether the battery cycle is updated, and when the battery cycle is updated, estimating SOH of the battery based on the pre-processed data.

For example, the method for predicting the battery state further includes performing machine learning based on the pre-processed data.

For example, the machine learning is based on at least one of decision tree learning, a support vector machine, a genetic algorithm, ANN, CNN, FNN, RNN, reinforcement learning, and an auto encoder.

For example, the method for predicting the battery state further includes outputting a state prediction result of the battery, which is generated based on the estimated SOH, to an outside.

For example, the calculating of the SOC value includes calculating a prediction SOC value and a prediction error covariance, calculating a Kalman gain based on the prediction SOC value and the prediction error covariance, calculating the SOC value and an error covariance based on the prediction SOC value, the prediction error covariance, the Kalman gain, and outputting the SOC value.

For example, the method for predicting the battery state further includes adjusting a parameter of the extended Kalman filter based on the estimated SOH.

### BRIEF DESCRIPTION OF THE FIGURES

The above and other objects and features of the present disclosure will become apparent by describing in detail embodiments thereof with reference to the accompanying drawings.

FIG. 1 is a block diagram schematically illustrating a battery state prediction device, according to an embodiment of the present disclosure.

FIG. 2 is a diagram illustrating a detailed configuration of a battery state prediction device shown in FIG. 1.

FIG. 3 is a diagram illustrating a detailed configuration of an SOC calculation unit illustrated in FIG. 2.

FIG. 4 is a diagram illustrating a detailed configuration of a data pre-processing unit shown in FIG. 2.

FIG. 5 is a diagram for describing an operation of an SOH estimation unit shown in FIG. 2.

FIG. 6 is a flowchart illustrating a battery state predicting method, according to an embodiment of the present disclosure.

FIG. 7 is a flowchart illustrating a method of calculating SOC, according to an embodiment of the present disclosure.

FIGS. 8A to 8C are graphs illustrating changes in data of a time-series domain for each SOH.

FIGS. 9A to 9C are graphs illustrating changes in data of a SOC domain for each SOH.

FIG. 10 is a view for disclosing an effect of a battery state prediction device, according to an embodiment of the present disclosure.

### DETAILED DESCRIPTION

Hereinafter, embodiments of the present disclosure will be described in detail and clearly to such an extent that an ordinary one in the art easily implements the present disclosure.

The terms used in the specification are provided to describe the embodiments, not to limit the present disclosure. As used in the specification, the singular terms “a,” “an” and “the” are intended to include the plural forms as well, unless the context clearly indicates otherwise. The terms “comprises” and/or “comprising,” when used in the specification, specify the presence of steps, operations, elements, and/or components, but do not preclude the presence or addition of one or more other steps, operations, elements, components, and/or groups thereof.

In the specification, the term “first and/or second” will be used to describe various elements but will be described only for the purpose of distinguishing one element from another element, not limiting an element of the corresponding term. For example, without departing the scope of the present disclosure, a first element may be referred to as a second element, and similarly, a second element may be referred to as a first element.

Unless otherwise defined, all terms (including technical and scientific terms) used in the specification should have the same meaning as commonly understood by those skilled in the art to which the present disclosure pertains. The terms, such as those defined in commonly used dictionaries, should not be interpreted in an idealized or overly formal sense unless expressly so defined herein. The same reference numerals represent the same elements throughout the specification.

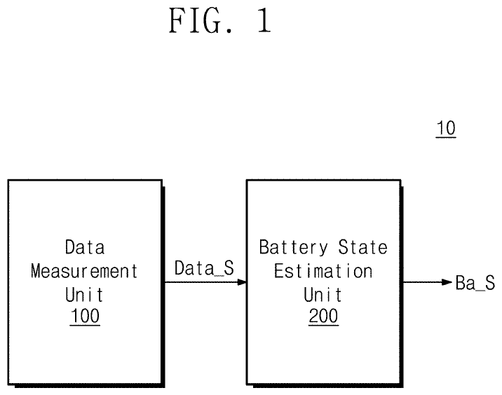

FIG. 1 is a block diagram schematically illustrating a battery state prediction device 10, according to an embodiment of the present disclosure. Referring to FIG. 1, the battery state prediction device 10 may include a data measurement unit 100 and a battery state estimation unit 200.

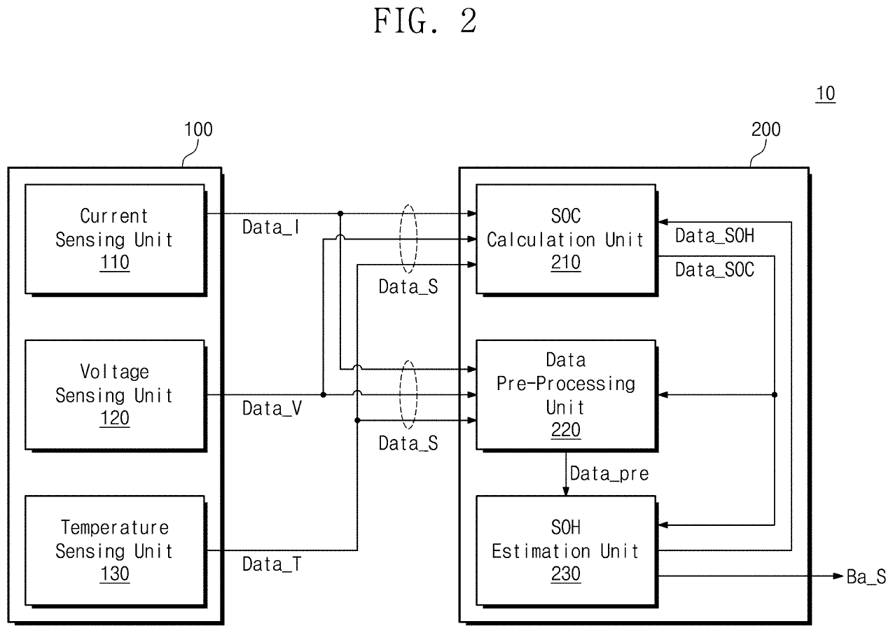

The data measurement unit 100 may measure information about a battery that is a target of state prediction. For example, the information about the battery measured by the data measurement unit 100 may include a current, a voltage, or a temperature. The data measurement unit 100 may transmit sensing data Data_S collected from the battery to the battery state estimation unit 200. The sensing data Data_S may be data of a time-series domain. The data measurement unit 100 may include a means for measuring battery information, and an embodiment thereof will be described in detail with reference to FIG. 2 to be described later.

The battery state estimation unit 200 may receive the sensing data Data_S from the data measurement unit 100. The battery state estimation unit 200 may calculate SOC of the battery based on the received sensing data Data_S. Moreover, the battery state estimation unit 200 may measure a battery cycle of the battery, which is a state prediction target, based on the estimated SOC. The battery state estimation unit 200 may pre-process the sensing data Data_S received from the data measurement unit 100. The battery state estimation unit 200 may estimate SOH of the battery based on the pre-processed sensing data Data_S. The battery state estimation unit 200 may output a prediction result Ba_S for a battery state to the outside based on the estimated SOH. The prediction result Ba_S for the battery state may include information about available capacity of the battery, a current level of the battery, or the remaining useful life of the battery. An operation of the battery state estimation unit 200 will be described in more detail with reference to FIG. 2 to be described later.

In estimating SOC based on information about a battery state measured by the data measurement unit 100, the battery state prediction device 10 according to an embodiment of the present disclosure may use an extended Kalman filter. The battery state prediction device 10 according to an embodiment of the present disclosure may measure a battery cycle based on the SOC estimated by using the extended Kalman filter. Besides, the battery state prediction device 10 according to an embodiment of the present disclosure may perform a pre-processing procedure of converting data of a time-series domain, which is associated with information about the battery state, into data of an SOC domain based on the estimated SOC. The battery state prediction device 10 according to an embodiment of the present disclosure may estimate SOH based on the pre-processed data. The battery state prediction device 10 according to an embodiment of the present disclosure may derive the prediction result Ba_S for an accurate battery state by estimating the SOH by using the data of the SOC domain.

Also, the battery state prediction device 10 according to an embodiment of the present disclosure may adjust a parameter of the extended Kalman filter based on the estimated SOH. In other words, the accuracy of the SOC estimation of the battery may be improved by feeding back the SOH estimation result of the battery. Furthermore, the battery state prediction device 10 according to an embodiment of the present disclosure may estimate the SOH based on machine learning without using a pre-estimation table method, thereby improving the accuracy of the prediction result Ba_S for a battery state by performing additional learning while the battery state prediction device 10 is operating, without requiring input of data for all battery state.

FIG. 2 is a diagram illustrating a detailed configuration of the battery state prediction device 10 (see FIG. 1) shown in FIG. 1. Referring to FIG. 2, the data measurement unit 100 included in the battery state prediction device 10 according to an embodiment of the present disclosure may include a current sensing unit 110, a voltage sensing unit 120, and a temperature sensing unit 130. Moreover, the battery state estimation unit 200 may include an SOC calculation unit 210, a data pre-processing unit 220, and an SOH estimation unit 230. Hereinafter, in the battery state prediction device 10 disclosed in FIG. 2, additional description associated with the components, functions, characteristics, and operations described with reference to FIG. 1 will be omitted to avoid redundancy.

The current sensing unit 110 may measure the amount of output current of a battery, which is a state prediction target, at specific time intervals and may output current data Data_I including information about the measured current value. For example, the current sensing unit 110 may measure the amount of accumulated output current from at a point in time when the battery is fully charged. The voltage sensing unit 120 may measure the output voltage of the battery, which is a state prediction target, at specific time intervals and may output voltage data Data_V including information about the measured voltage value. The temperature sensing unit 130 may measure a temperature change amount of the battery, which is the state prediction target, at specific time intervals and may output temperature data Data_T including information about the measured temperature change amount. The sensing data Data_S including the current data Data_I, the voltage data Data_V, and the temperature data Data_T may be delivered to the SOC calculation unit 210 and the data pre-processing unit 220 of the battery state estimation unit 200.

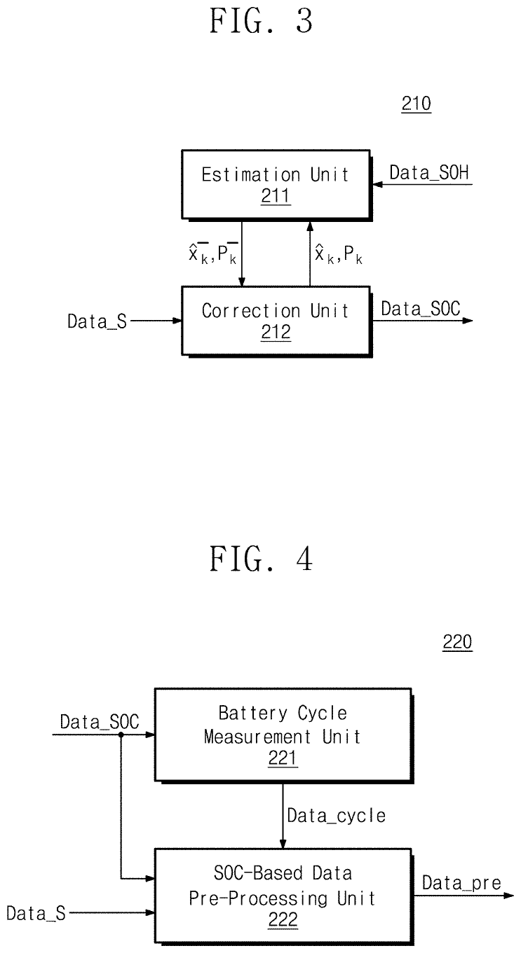

The SOC calculation unit 210 may calculate SOC of the battery based on the sensing data Data_S delivered from the data measurement unit 100. In calculating the SOC, the SOC calculation unit 210 may use an extended Kalman filter. The SOC calculation unit 210 may deliver SOC data Data_SOC including the calculated SOC information to the data pre-processing unit 220 and the SOH estimation unit 230. A detailed configuration of the SOC calculation unit 210 and a method of calculating SOC by using the extended Kalman filter will be described in detail with reference to FIG. 3 to be described later.

The data pre-processing unit 220 may measure a battery cycle of the battery based on the SOC data Data_SOC delivered from the SOC calculation unit 210 and may generate battery cycle data Data_cycle including battery cycle information. Furthermore, the data pre-processing unit 220 may pre-process the generated battery cycle data Data_cycle and the sensing data Data_S delivered from the data measurement unit 100. The data pre-processing unit 220 may deliver pre-processed data Data_pre to the SOH estimation unit 230. Moreover, although not shown in drawings, the data pre-processing unit 220 may store the pre-processed data Data_pre in a buffer. The buffer may be a component included in the data pre-processing unit 220 or may be a component separate from the data pre-processing unit 220. A detailed configuration of the data pre-processing unit 220 and a pre-processing method of data will be described in detail with reference to FIG. 4 to be described later.

The SOH estimation unit 230 may estimate SOH of the battery based on the SOC data Data_SOC delivered from the SOC calculation unit 210 and the pre-processed data Data_pre delivered from the data pre-processing unit 220. The SOH estimation unit 230 may estimate the SOH of the battery based on machine learning. For example, a machine learning model used in the SOH estimation unit 230 may include at least one of decision tree learning, a support vector machine, a genetic algorithm, an artificial neural network (ANN), a convolutional neural network (CNN), a feedforward neural network (FNN), a recurrent neural network (RNN), reinforcement learning, and an auto encoder.

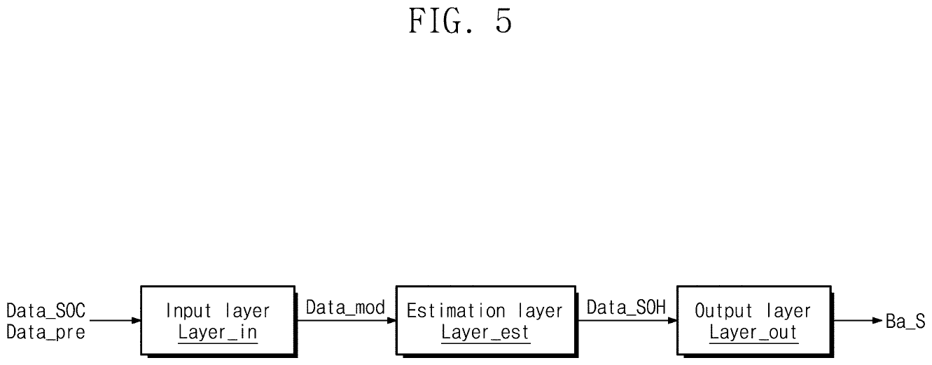

The SOH estimation unit 230 may output SOH data Data_SOH including information about the estimated SOH of the battery to the SOC calculation unit 210. Besides, the SOH estimation unit 230 may output the prediction result Ba_S for a battery state to the outside based on the information about the estimated SOH of the battery. A machine learning principle and SOH estimation method of the SOH estimation unit 230 will be described in detail with reference to FIG. 5 to be described later.

FIG. 3 is a diagram illustrating a detailed configuration of the SOC calculation unit 210 illustrated in FIG. 2. Referring to FIG. 3, the SOC calculation unit 210 may include an estimation unit 211 and a correction unit 212.

The estimation unit 211 may calculate a prediction SOC value and a prediction error covariance. An operation on a prediction SOC value performed by the estimation unit 211 may be performed depending on Equation 1. In Equation 1, \hat{X}ₖ⁻ denotes the k-th prediction SOC value, and \hat{X}ₖ₋₁ denotes the (k−1)-th SOC value. When a battery is expressed as a Thevenin equivalent circuit, C₁ denotes a value of a capacitor. When the battery is expressed as a Thevenin equivalent circuit, R₁ denotes a resistance value. Q means a process noise covariance, and lₖ denotes the k-th measured current value.

$${\hat{x}}_{k}^{-} = f ( {\hat{x}}_{k - 1} ) \qquad [ Equation 1 ]$$

$$f ( {\hat{x}}_{k} ) = [ \begin{matrix}1 & 0 \\ 0 & exp ( - \frac{δ t}{{C}_{1} {R}_{1}} )\end{matrix} ] {\hat{x}}_{k} + [ \begin{matrix}- \frac{δ t}{{Q}_{max}} \\ {R}_{1} ( 1 - exp ( - \frac{δ t}{{C}_{1} {R}_{1}} ) )\end{matrix} ] {I}_{k}$$

An operation on the prediction error covariance performed by the estimation unit 211 may be performed depending on Equation 2. Pₖ⁻ denotes the prediction error covariance, and pₖ₋₁ denotes the (k−1)-th derived error covariance. When a battery is expressed as a Thevenin equivalent circuit, C denotes a value of a capacitor. When the battery is expressed as a Thevenin equivalent circuit, R₁ denotes a resistance value.

$${P}_{k}^{-} = {AP}_{k - 1} {A}^{T} + Q \\ A = [ \begin{matrix}1 & 0 \\ 0 & exp ( - \frac{δ t}{{C}_{1} {R}_{1}} )\end{matrix} ] \qquad [ Equation 2 ]$$

The estimation unit 211 may deliver a prediction SOC value and a prediction error covariance to the correction unit 212.

The correction unit 212 may receive the sensing data Data_S delivered from the data measurement unit 100. The correction unit 212 may calculate a Kalman gain, an SOC value, and an error covariance. A Kalman gain operation performed by the correction unit 212 may be performed depending on Equation 3. Kₖ denotes the Kalman gain; Pₖ⁻ denotes the k-th derived error covariance; and R denotes measurement noise.

$${K}_{k} = {P}_{k}^{-} {{H}^{T} ( {HP}_{k}^{-} {H}^{T} + R )}^{- 1} \\ H = [ \frac{δ OCV}{δ SOC} - 1 ] \\ OCV = 2.58 SOC + 3.81 {e}^{- 0.84 SOC} - 0.3 {e}^{- 8.3 SOC} \qquad [ Equation 3 ]$$

An SOC value operation performed by the correction unit 212 may be performed depending on Equation 4. \hat{X}ₖ denotes an SOC value; denotes a prediction SOC value; Kₖ denotes a Kalman gain; and, Zₖ denotes the sensing data Data_S.

\hat{x}ₖ=\hat{x}ₖ⁻+Kₖ(zₖ−h(\hat{x}ₖ⁻)) [Equation 4]

An error covariance operation performed by the correction unit 212 may be performed depending on Equation 5. Pₖ denotes an error covariance; Pₖ⁻ denotes a prediction error covariance; k denotes a Kalman gain; and H corresponds to H derived from Equation 3.

Pₖ=Pₖ⁻−KₖHPₖ⁻ [Equation 5]

The SOC data Data_SOC including information about the SOC value calculated by the correction unit 212 may be delivered to the data pre-processing unit 220 (see FIG. 2) and the SOH estimation unit 230 (see FIG. 2). The SOC value and error covariance calculated by the correction unit 212 may be delivered to the estimation unit 211. In addition, the SOH data Data_SOH (see FIG. 2) output from the SOH estimation unit 230 (see FIG. 2) may be delivered to the estimation unit 211 of the SOC calculation unit 210, and then A and Q, which are coefficients of Equation 2, may be updated.

The SOC calculation unit 210 may accurately calculate the SOC value by adjusting a parameter of the extended Kalman filter based on the SOH data Data_SOH. The SOH estimation unit 230 may accurately estimate the SOH of the battery based on the calculated SOC value.

FIG. 4 is a diagram illustrating a detailed configuration of the data pre-processing unit 220 shown in FIG. 2. Referring to FIG. 4, the data pre-processing unit 220 may include a battery cycle measurement unit 221 and an SOC-based data pre-processing unit 222.

The battery cycle measurement unit 221 may receive the SOC data Data_SOC from the SOC calculation unit 210 (see FIG. 2). The battery cycle measurement unit 221 may generate battery cycle data Data_cycle including information about a battery cycle based on the SOC data Data_SOC. When a battery is fully charged again or at a specified ratio or more after the battery is discharged completely or at a specified ratio or less in a state where a battery, which is a state prediction target, is charged fully or at a predetermined ratio or more, the battery cycle may be increased by one. For example, when a procedure in which the battery is completely discharged from a fully charged state is repeated twice, and then the battery is fully charged again, the battery cycle may be 2. The battery cycle measurement unit 221 may deliver the generated battery cycle data Data_cycle to the SOC-based data pre-processing unit 222.

The SOC-based data pre-processing unit 222 may receive the SOC data Data_SOC from the SOC calculation unit 210. Furthermore, the SOC-based data pre-processing unit 222 may receive the sensing data Data_S from the data measurement unit 100 (see FIG. 1). The sensing data Data_S may include the current data Data_I (see FIG. 2) output from the current sensing unit 110 (see FIG. 2) and the voltage data Data_V (see FIG. 2) output from the voltage sensing unit 120 (see FIG. 2) and the temperature data Data_T (see FIG. 2) output from the temperature sensing unit 130 (see FIG. 2).

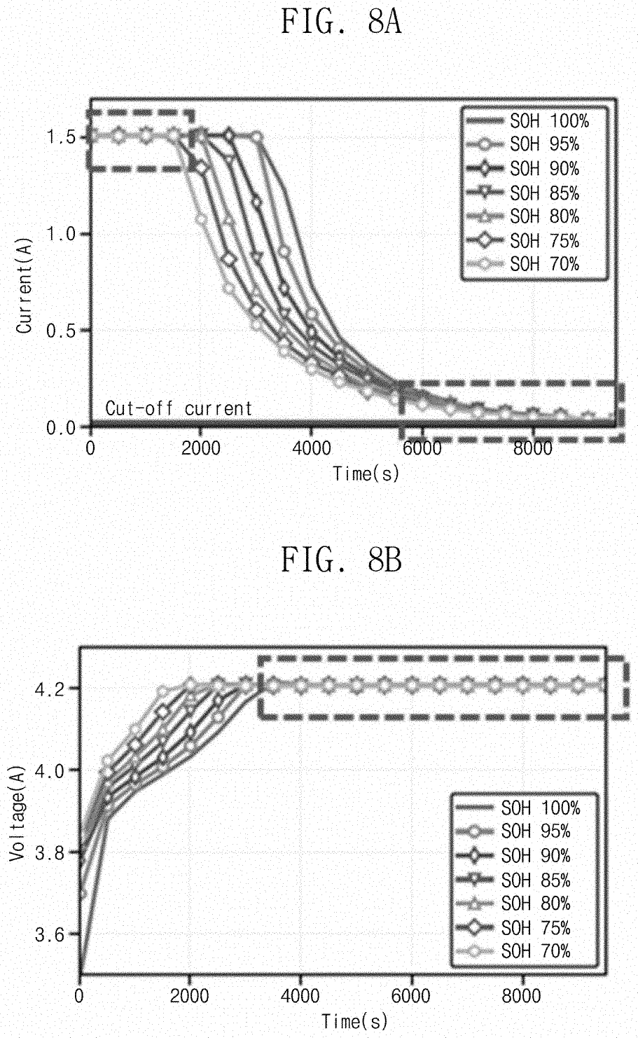

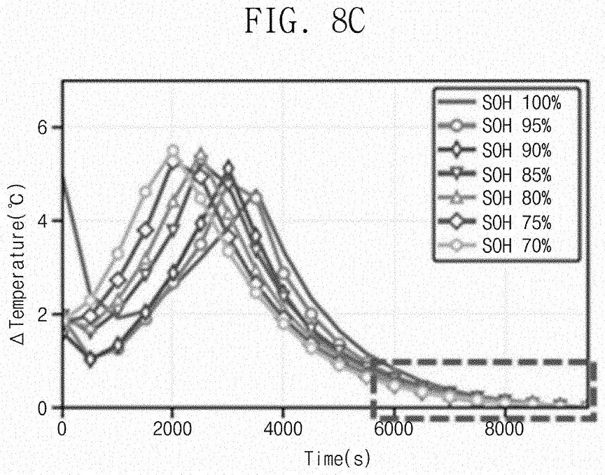

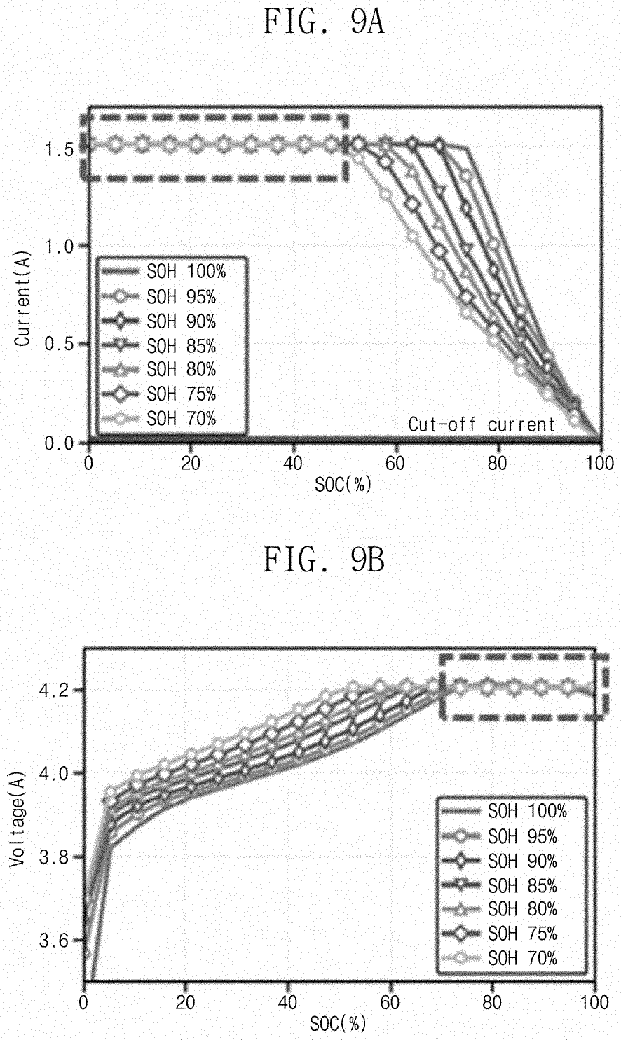

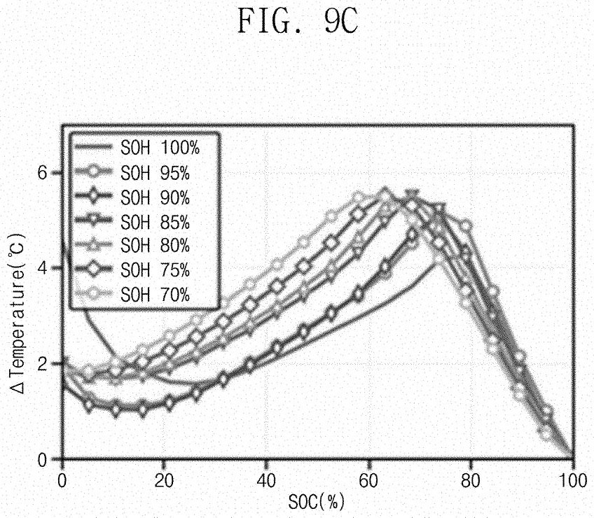

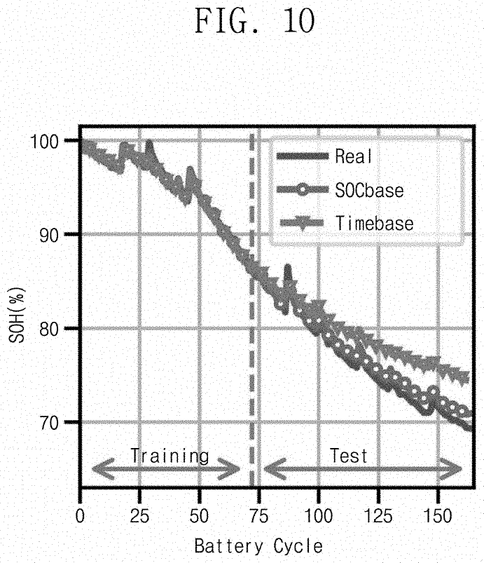

The SOC-based data pre-processing unit 222 may perform a pre-processing procedure of converting the sensing data Data_S, which is time-series domain-based data, into SOC domain-based data. The SOC-based data pre-processing unit 222 may convert the sensing data Data_S of the time-series domain into the pre-processed data Data_pre of the SOC domain based on the SOC data Data_SOC received from the SOC calculation unit 210. The battery state prediction device 10 according to the present disclosure may estimate SOH of the battery by using the pre-processed data Data_pre of the SOC domain, thereby improving the accuracy of battery state prediction. Effects obtained by using the time-series-based data and the SOC-based data will be described in detail with reference to FIGS. 8A to 9C, which will be described later.

FIG. 5 is a diagram for describing an operation of the SOH estimation unit 230 shown in FIG. 2. As described above, the SOH estimation unit 230 of the battery state prediction device 10 (see FIG. 1) according to the present disclosure may perform machine learning based on a network model of at least one of decision tree learning, a support vector machine, a genetic algorithm, ANN, CNN, FNN, RNN, reinforcement learning, and an auto encoder. To estimate SOH of a battery based on machine learning, the SOH estimation unit 230 may include an input layer Layer_in, an estimation layer Layer_est, and an output layer Layer_out.

The input layer Layer_in may receive the SOC data Data_SOC delivered from the SOC calculation unit 210 (see FIG. 2) and the cycle data Data_cycle and the pre-processed data Data_pre, which are delivered from the data pre-processing unit 220 (see FIG. 2). The input layer Layer_in may modify a format of the received input data to be suitable for the estimation layer Layer_est. The input layer Layer_in may deliver format-modified data Data_mod to the estimation layer Layer_est.

The estimation layer Layer_est may estimate SOH of the battery by performing machine learning on the format-modified data Data_mod. The estimation layer Layer_est may deliver the SOH data Data_SOH including the estimated SOH information to the output layer Layer_out.

The output layer Layer_out may derive the prediction result Ba_S for a battery state based on the SOH data Data_SOH. The output layer Layer_out may modify a format of the SOH data Data_SOH to be suitable for the format of the prediction result Ba_S for the battery state, which is to be derived. The output layer Layer_out may deliver the derived prediction result Ba_S for the battery state to the outside. Furthermore, although not shown in drawings, the output layer Layer_out may deliver the SOH data Data_SOH to the SOC calculation unit 210. The SOC calculation unit 210 may adjust an extended Kalman filter based on the delivered SOH data Data_SOH.

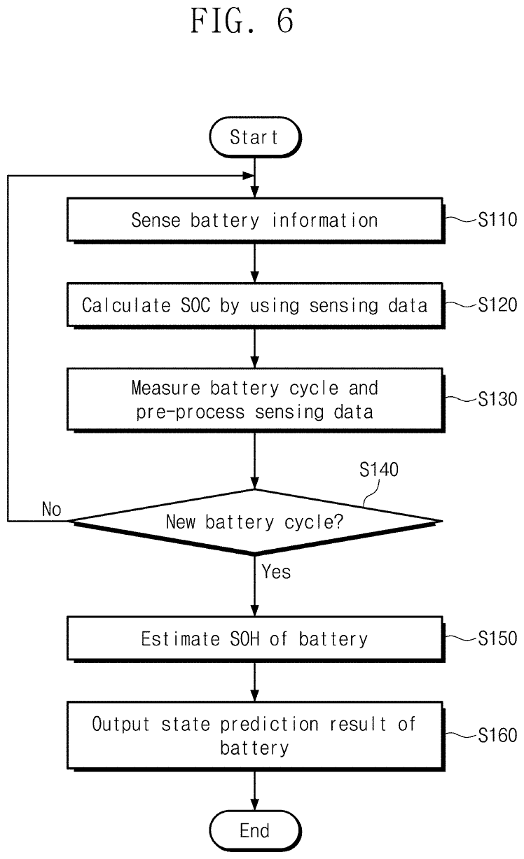

FIG. 6 is a flowchart illustrating a battery state predicting method, according to an embodiment of the present disclosure. Hereinafter, in a battery state predicting method disclosed in FIG. 6, additional description associated with the components, functions, characteristics, and operations described with reference to FIGS. 1 to 5 will be omitted to avoid redundancy.

In operation S110, the data measurement unit 100 (see FIG. 1) of the battery state prediction device 10 (see FIG. 1) according to an embodiment of the present disclosure may sense information about a battery that is a state prediction target. For example, the information about the battery may include changes in current, voltage, or temperature measured from the battery. The data measurement unit 100 may deliver the sensing data Data_S (see FIG. 1) including the information about the battery to the battery state estimation unit 200 (see FIG. 2) and the data pre-processing unit 220 (see FIG. 2).

In operation S120, the SOC calculation unit 210 (see FIG. 2) of the battery state estimation unit 200 may calculate SOC based on the sensing data Data_S. The SOC calculation unit 210 may derive the SOC by using an extended Kalman filter. The SOC calculation unit 210 may deliver the SOC data Data_SOC including the derived SOC information to the data pre-processing unit 220 and the SOH estimation unit 230.

In operation S130, the data pre-processing unit 220 may measure the battery cycle of the battery, and may pre-process the sensing data Data_S based on the battery cycle information of the battery and the SOC data Data_SOC. The sensing data Data_S based on a time-series domain may be converted into the pre-processed data Data_pre based on the SOC domain through pre-processing. The pre-processed data Data_pre may be stored in a buffer to perform machine learning. The data pre-processing unit 220 may deliver pre-processed data Data_pre to the SOH estimation unit 230 (see FIG. 2).

In operation S140, the SOH estimation unit 230 may determine whether the battery cycle is updated. When the battery cycle measured from the data pre-processing unit 220 is a new battery cycle, the process may proceed to operation S150. On the other hand, when the battery cycle measured from the data pre-processing unit 220 is not a new battery cycle, the process may return to operation S110.

In operation S150, the SOH estimation unit 230 may estimate SOH of the battery based on the pre-processed data Data_pre. The SOH estimation unit 230 may generate the SOH data Data_SOH (see FIG. 2) including SOH information of the battery. To update a coefficient of the extended Kalman filter, the SOH estimation unit 230 may provide the SOH data Data_SOH to the SOC calculation unit 210.

In operation S160, the SOH estimation unit 230 may output the state prediction result Ba_S (see FIG. 1) of the battery to the outside based on the SOH data Data_SOH. After the state prediction result Ba_S of the battery is output, the process ends.

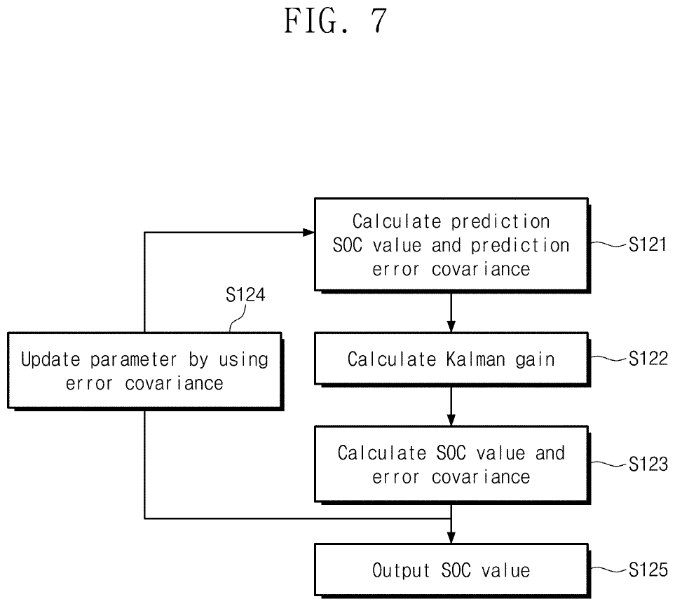

FIG. 7 is a flowchart illustrating a method of calculating SOC, according to an embodiment of the present disclosure. In an SOC calculating method disclosed in FIG. 7, additional description associated with the components, functions, characteristics, and operations described with reference to FIGS. 1 to 5 will be omitted to avoid redundancy.

In operation S121, the estimation unit 211 (see FIG. 3) of the SOC calculation unit 210 (see FIG. 2) may calculate a prediction SOC value and a prediction error covariance based on the sensing data Data_S (see FIG. 1). The prediction SOC value and the prediction error covariance may be derived based on Equation 1 and Equation 2 described above. The estimation unit 211 may deliver the derived prediction SOC value and prediction error covariance to the correction unit 212 (see FIG. 3) of the SOC calculation unit 210.

In operation S122, the correction unit 212 may calculate a Kalman gain based on the prediction error covariance. The Kalman gain may be derived based on Equation 3 above.

In operation S123, the correction unit 212 may calculate an SOC value based on the sensing data Data_S, the Kalman gain, and the prediction SOC value. The SOC value may be derived based on Equation 4 described above. Moreover, the correction unit 212 may calculate an error covariance based on the Kalman gain and the prediction SOC value. The error covariance may be derived based on Equation 5 described above. The correction unit 212 may deliver the derived error covariance to the estimation unit 211.

In operation S124, the estimation unit 211 may update a parameter of the estimation unit 211 by using the delivered error covariance. In other words, the estimation unit 211 and the correction unit 212 may update a calculation parameter through a mutual feedback operation.

In operation S125, the correction unit 212 may output the calculated SOC value to the data pre-processing unit 220 (see FIG. 2) and the SOH estimation unit 230 (see FIG. 2).

FIGS. 8A to 8C are graphs illustrating changes in data of a time-series domain for each SOH. In more detail, FIG. 8A shows a change in current data based on a time-series domain for each SOH; FIG. 8B shows a change in voltage data based on the time-series domain for each SOH; and, FIG. 8C shows a change in temperature data based on the time-series domain for each SOH.

FIGS. 9A to 9C are graphs illustrating changes in data of a SOC domain for each SOH. In more detail, FIG. 9A shows a change in current data based on an SOC domain for each SOH; FIG. 9B shows a change in voltage data based on the SOC domain for each SOH; and, FIG. 9C shows a change in temperature change data based on the SOC domain for each SOH.

Referring to FIG. 8A, it may be understood that 12 pieces of data among 20 pieces of time-series domain-based current data are the same as one another regardless of SOH. On the other hand, referring to FIG. 9A, it may be understood that 10 pieces of data among 20 pieces of SOC domain-based current data are the same as one another regardless of SOH. That is, it may be understood that the SOC domain-based current data is changed more significantly than the time-series-based current data depending on SOH.

Referring to FIG. 8B, it may be understood that 13 pieces of data among 20 pieces of time-series domain-based voltage data are the same as one another regardless of SOH. On the other hand, referring to FIG. 9B, it may be understood that only 6 pieces of data among 20 pieces of SOC domain-based voltage data are the same as one another regardless of SOH. That is, it may be understood that the SOC domain-based voltage data is changed more significantly than the time-series-based voltage data depending on SOH.

Referring to FIG. 8C, it may be understood that 8 pieces of data among 20 pieces of time-series domain-based temperature change data are the same as one another regardless of SOH. On the other hand, referring to FIG. 9C, it may be understood that there is no point having the same value in SOC domain-based temperature change data. That is, it may be understood that the SOC domain-based temperature change data is changed more significantly than the time-series-based temperature change data depending on SOH.

Because the amount of change in current, voltage, and temperature of a battery does not change linearly with time but has a high relationship with the energy stored inside, such the result may be derived. The battery state prediction device 10 (see FIG. 1) according to an embodiment of the present disclosure may perform a pre-processing process of converting time-series domain-based data into SOC domain-based data and may estimate SOH by using the SOC domain-based data, thereby accurately predicting a battery state.

FIG. 10 is a view for disclosing an effect of the battery state prediction device 10 (see FIG. 1) according to an embodiment of the present disclosure. In more detail, FIG. 10 is a view showing SOH estimated from the SOH estimation unit 230 (see FIG. 2) that performs machine learning. In the embodiment disclosed in FIG. 10, the machine learning has been performed based on an FNN model. In FIG. 10, a graph indicated by a solid line shows SOH of a real battery; a graph indicated by a circle shows the SOH of the battery estimated by using SOC domain-based data; and, a graph indicated by a triangle shows the SOH of the battery estimated by using time-series domain-based data.

In an embodiment shown in FIG. 10, until a battery cycle of the battery reaches 75, the SOH estimation unit 230 has performed machine learning. Afterward, the SOH estimation unit 230 estimates the SOH of the battery at the battery cycle. Referring to FIG. 10, it may be understood that the SOH of the battery estimated by using SOC domain-based data is similar to the SOH of the real battery as compared to the SOH of the battery estimated by using time-series domain-based data. That is, the battery state prediction device 10 according to an embodiment of the present disclosure may estimate the SOH of the battery by using SOC domain-based data, thereby accurately predicting a battery state as compared to a case of estimating the SOH of the battery by using time-series domain-based data.

However, in FIG. 10, it is assumed that machine learning has been performed until the battery cycle of the battery reached 75, but it is only one example. The running time of the machine learning of the SOH estimation unit 230 is not limited thereto. For example, until the battery cycle reaches 125, the SOH estimation unit 230 may perform machine learning. Alternatively, the SOH estimation unit 230 may continuously perform machine learning regardless of a battery cycle.

The above description refers to embodiments for implementing the present disclosure. Embodiments in which a design is changed simply or which are easily changed may be included in the inventive concept as well as an embodiment described above. In addition, technologies that are easily changed and implemented by using the above embodiments may be included in the present disclosure. Accordingly, it will be apparent to those of ordinary skill in the art that various changes and modifications may be made to the above embodiments without departing from the spirit and scope of the invention as set forth in the following claims

According to an embodiment of the present disclosure, as compared to using data in a time-series domain, it is possible to accurately extract characteristics associated with SOH of a battery by using data measured in an SOC domain of the battery.

According to an embodiment of the present disclosure, it is possible to adjust parameters of an extended Kalman filter based on the estimated SOH, thereby calculating accurate SOC and estimating accurate SOH based on the calculated SOC.

According to an embodiment of the present disclosure, a battery state may be accurately estimated by estimating SOH of the battery based on machine learning.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A battery state prediction device comprising:
a data measurement unit configured to measure information about a battery and to output first data; and
a battery state estimation unit configured to calculate a state of charge (SOC) value of the battery based on the first data, to generate second data by pre-processing the first data based on the SOC value, and to estimate a state of health (SOH) of the battery based on the second data,
wherein the battery state estimation unit calculates the SOC value based on an extended Kalman filter and adjusts a parameter of the extended Kalman filter based on the estimated SOH.

2. The battery state prediction device of claim 1, wherein the data measurement unit includes:
a current sensing unit configured to measure current information of the battery and to generate current data including the current information;
a voltage sensing unit configured to measure voltage information of the battery and to generate voltage data including the voltage information; and
a temperature sensing unit configured to measure temperature change information of the battery and to generate temperature change data including the temperature change information,
wherein the first data includes the current data, the voltage data, and the temperature change data.

3. The battery state prediction device of claim 1, wherein the battery state estimation unit includes:
an SOC calculation unit configured to calculate the SOC value and to output the SOC value;
a data pre-processing unit configured to receive the SOC value, to generate the second data by pre-processing the first data based on the SOC value, and to output the second data; and
an SOH estimation unit configured to receive the second data and to estimate the SOH based on the second data.

4. The battery state prediction device of claim 3, wherein the SOC calculation unit includes:
an estimation unit configured to calculate a prediction SOC value and a prediction error covariance and to output the prediction SOC value and the prediction error covariance; and
a correction unit configured to receive the prediction SOC value and the prediction error covariance, to calculate the SOC value and an error covariance based on the prediction SOC value, the prediction error covariance, and the first data, and to deliver the SOC value and the error covariance to the estimation unit.

5. The battery state prediction device of claim 3, wherein the data pre-processing unit includes:
a battery cycle measurement unit configured to measure a battery cycle; and
an SOC-based data pre-processing unit configured to pre-process the first data based on the battery cycle and the SOC value.

6. The battery state prediction device of claim 5, wherein the pre-processed first data is stored in a buffer.

7. The battery state prediction device of claim 3, wherein the SOH estimation unit performs machine learning.

8. The battery state prediction device of claim 7, wherein the machine learning is based on at least one of decision tree learning, a support vector machine, a genetic algorithm, an artificial neural network (ANN), a convolutional neural network (CNN), a feedforward neural network (FNN), a recurrent neural network (RNN), reinforcement learning, and an auto encoder.

9. The battery state prediction device of claim 1, wherein the battery state estimation unit outputs a state prediction result of the battery, which is generated based on the estimated SOH, to an outside, and
wherein the state prediction result of the battery includes at least one of available capacity of the battery, a current level of the battery, or a remaining useful life of the battery.

10. A method for predicting a battery state, the method comprising:
sensing information about a battery;
calculating an SOC value by using an extended Kalman filter based on the sensed information about the battery;
measuring a battery cycle of the battery;
pre-processing data including the sensed information about the battery based on the SOC value and the battery cycle;
determining whether the battery cycle is updated; and
when the battery cycle is updated, estimating SOH of the battery based on the pre-processed data.

11. The method of claim 10, further comprising:
performing machine learning based on the pre-processed data.

12. The method of claim 11, wherein the machine learning is based on at least one of decision tree learning, a support vector machine, a genetic algorithm, ANN, CNN, FNN, RNN, reinforcement learning, and an auto encoder.

13. The method of claim 10, further comprising:
outputting a state prediction result of the battery, which is generated based on the estimated SOH, to an outside.

14. The method of claim 10, wherein the calculating of the SOC value includes:
calculating a prediction SOC value and a prediction error covariance;
calculating a Kalman gain based on the prediction SOC value and the prediction error covariance;
calculating the SOC value and an error covariance based on the prediction SOC value, the prediction error covariance, the Kalman gain; and
outputting the SOC value.

15. The method of claim 10, further comprising:
adjusting a parameter of the extended Kalman filter based on the estimated SOH.
